(19) United States
(12) Patent Application Publication
(10) Pub. No.: US 2022/0037298 A1
(43) Pub. Date: Feb. 3, 2022

(54) DISPLAY MODULE, PREPARATION METHOD THEREOF, AND ELECTRONIC DEVICE

(71) Applicant: Shenzhen China Star Optoelectronics Semiconductor Display Technology Co., Ltd., Shenzhen (CN)

(72) Inventors: Pei JIANG, Shenzhen (CN); Yong FAN, Shenzhen (CN); Minggang LIU, Shenzhen (CN)

(73) Assignee: Shenzhen China Star Optoelectronics Semiconductor Display Technology Co., Ltd., Shenzhen (CN)

(21) Appl. No.: 16/765,173

(22) PCT Filed: Jan. 8, 2020
(86) PCT No.: PCT/CN2020/070839

§ 371 Date: May 19, 2020

(30) Foreign Application Priority Data
Dec. 16, 2019 (CN) 201911289952.9

(51) Int. Cl. H01L 25/16

(52) U.S. Cl. CPC H01L 25/167

(57) ABSTRACT

The present disclosure provides a display module, a preparation method thereof, and an electronic device of the present disclosure. The display module includes a bending flexible driving substrate and display unit. The bending flexible driving substrate includes a display area, a bending area, and a binding area, wherein the bending flexible driving substrate has a cavity, the display unit is bound to the display area, wherein the display unit includes a plurality of miniature light-emitting diodes, the support body is provided in the cavity, and a shape of a longitudinal section of the support body is a rounded rectangle.

### FIELD OF INVENTION

The present disclosure relates to the technical field of display, and in particular, relates to a display module, a preparation method thereof, and an electronic device.

### BACKGROUND OF INVENTION

Compared to liquid crystal display panels and organic light-emitting diode (OLED) display panels, the miniature light-emitting diode (Mini/Micro-LED) display panels have become the next-generation mainstream display technology due to the advantages of strong color reproduction, wide viewing angles, high refresh rates, high contrast, high stability, low power consumption, and high grayscales.

At present, a Mini/Micro-LED display panel is bent along a bending area to bend the binding area to the back of the display area to obtain a display module. However, during the bending process of the existing display panel, due to the large stress, the display area is easily damaged, thereby reducing the product yield.

As a result, it is necessary to provide a display module, a preparation method thereof, and an electronic device to solve the problems existing in the conventional technologies, as described above.

### SUMMARY OF INVENTION

An object of the present disclosure is to provide a display module, the preparation method thereof, and an electronic device, which can reduce display area damage and improve product yield.

To achieve the above object, the present disclosure provides display module, comprising:

a support body; and

a display panel, wherein a cross-sectional structure of the display panel includes:

a bending flexible driving substrate including a display area, a bending area, and a binding area, wherein the bending flexible driving substrate has a cavity; and

a display unit bound to the display area, wherein the display unit includes a plurality of miniature light-emitting diodes;

wherein the support body is provided in the cavity, and a shape of a longitudinal section of the support body is rounded rectangle.

The present disclosure further provides a preparation method of a display module, comprising steps of:

preparing a flexible driving substrate on a glass substrate;

moving a miniature light-emitting diode chip to the flexible driving substrate and performing an encapsulation to obtain a display panel, wherein the miniature light-emitting diode chip includes a plurality of miniature light-emitting diodes;

bonding a flip-chip film in a binding area of the display panel;

providing a flexible protective film on the display panel;

removing the glass substrate under the flexible driving substrate;

attaching the support body to a side of the display panel located in a display area away from the miniature light-emitting diode chip, wherein a shape of a longitudinal section of the support body is rounded rectangle; and

bending a bending area of the display panel and attaching the display panel to the support body.

The present disclosure further provides an electronic device, comprising said display module.

The display module, the preparation method thereof, and the electronic device of the present disclosure, the display module includes a support body and a display panel, wherein a cross-sectional structure of the display panel includes: a bending flexible driving substrate including a display area, a bending area, and a binding area, wherein the bending flexible driving substrate has a cavity; and a display unit bound to the display area, wherein the display unit includes a plurality of miniature light-emitting diodes; wherein the support body is provided in the cavity, and a shape of a longitudinal section of the support body is a rounded rectangle. As a result of the shape of the longitudinal section of the support body being a rounded rectangle, the impact of large stress in the bending area is avoided, thereby avoiding damage to the display area and improving product yields.

### DESCRIPTION OF DRAWINGS

FIG. 1 is a schematic structural view of a first step of a preparation method of a display module according to the present disclosure.

FIG. 2 is a schematic structural view of a second step of the preparation method of the display module according to the present disclosure.

FIG. 3 is a schematic structural view of a third step of the preparation method of the display module according to the present disclosure.

FIG. 4 is a schematic structural view of a fourth step of the preparation method of the display module according to the present disclosure.

FIG. 5 is a schematic structural view of a fifth step of the preparation method of the display module according to the present disclosure.

FIG. 6 is a schematic structural view of a sixth step of the preparation method of the display module according to the present disclosure.

FIG. 7 is a schematic structural view of a seventh step of the preparation method of the display module according to the present disclosure.

FIG. 8 is a schematic structural view of a support body according to the present disclosure.

FIG. 9 is a schematic structural view of a display device according to the present disclosure.

### DETAILED DESCRIPTION OF PREFERRED EMBODIMENTS

Structural and technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, longitudinal/vertical, transverse/horizontal, etc., are only directions by referring to the accompanying drawings, and thus the used directional terms are used to describe and understand the present disclosure, but the present disclosure is not limited thereto.

The terms “first”, “second”, and the like in the description and claims of the present disclosure and the above-mentioned drawings are used to distinguish different objects, and are not used to describe a specific order. Furthermore, the terms “including” and “having” and any variations thereof are intended to cover non-exclusive inclusion.

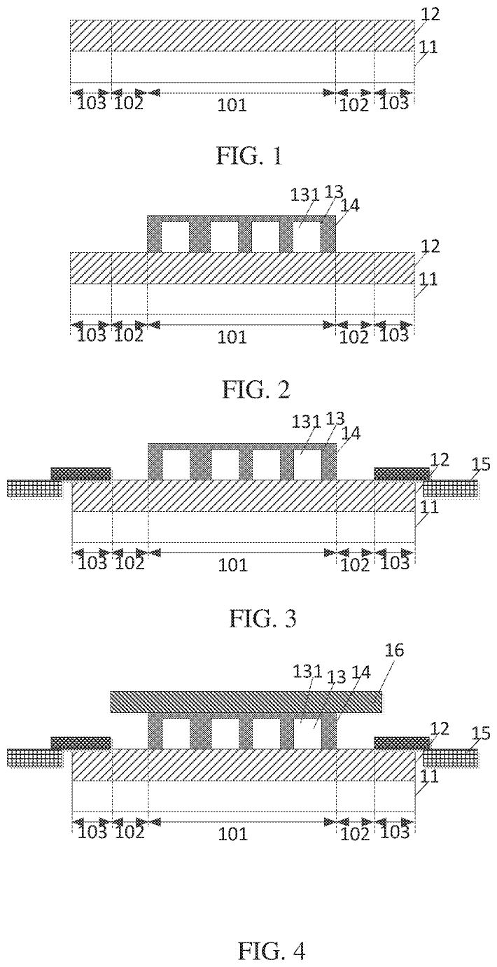

Referring to FIG. 1 to FIG. 9, FIG. 1 is a schematic structural view of a first step of a preparation method of a display module according to the present disclosure.

In one embodiment, the present disclosure further provides a preparation method of a display module, comprising steps as follows.

In step S101, preparing a flexible driving substrate on a glass substrate.

For example, as shown in FIG. 1, a flexible driving substrate 12 is prepared on a glass substrate 11, wherein the flexible driving substrate 12 includes a flexible substrate and a driving layer provided on the flexible substrate. The flexible substrate is a bendable substrate formed by the flexible material, and the flexible substrate is stretchable or bendable. The material may include, but is not limited to, polyimide (PI), polyethylene terephthalate (PET), and polycarbonate (PC). It may also be other flexible materials, which are not limited herein. The thickness of the flexible substrate may be set based on empirical values. The driving layer includes a plurality of thin film transistors. A cross-sectional structure of the driving layer includes an active layer, a gate layer, a source-drain layer, a gate insulating layer disposed between the active layer and the gate layer, and an interlayer insulating layer provided between the gate layer and the source-drain layer. In the embodiment, the thin film transistor may be one of a top gate thin film transistor, a bottom gate thin film transistor, a single gate thin film transistor, and a double gate thin film transistor, which are not limited herein.

In step S102, moving a miniature light-emitting diode (Mini/Micro-LED) chip onto the flexible driving substrate and performing an encapsulation to obtain a display panel.

As shown in FIG. 2, the miniature light-emitting diode chip 13 includes a plurality of miniature light-emitting diodes 131, and the miniature light-emitting diode chip 13 is moved onto the flexible driving substrate 12. A flexible miniature light-emitting diode display panel is obtained through precision performing an encapsulation, wherein the miniature light-emitting diode chip 13 is electrically connected to the flexible driving substrate 12.

In one embodiment, the miniature light-emitting diode chip 13 may be packaged by using a encapsulating film 14, wherein the flatness range of the encapsulating film 14 reaches ±10 μm.

In step S103, bonding a flip-chip film into a binding area of the display panel.

As shown in FIG. 3, the flip-chip film 15 is bound into the binding area 103 of the display panel.

In step S104, providing a flexible protective film on the display panel.

As shown in FIG. 4, the outer lead bonding (OLB) area is protected by using a flexible protective film 16, and the flexible protective film 16 can support the flexible driving substrate 12 there below.

In step S105, removing the glass substrate under the flexible driving substrate.

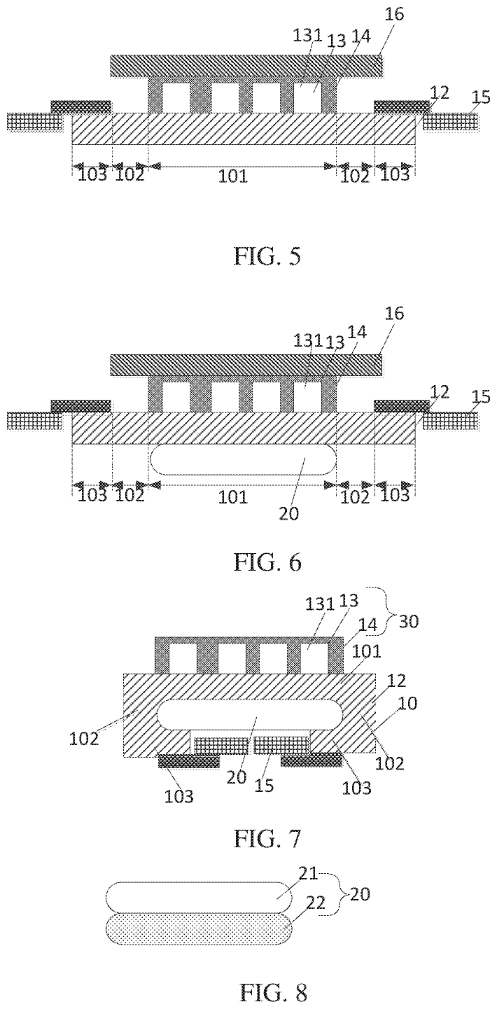

As shown in FIG. 5, in one embodiment, the glass substrate 11 is removed by a laser lift off process (LLO). In addition, a part of the flexible driving substrate 12 adjacent to the flip-chip film is cut off by a laser cutting process, and a part of the flexible driving substrate 12 at both ends is cut off, so that the width of the flexible driving substrate 12 is narrowed.

In step S106, attaching the support body to a side of the display panel located in a display area away from the miniature light-emitting diode chip 13.

As shown in FIG. 6, the colloid is coated on the lower surface of the flexible driving substrate 12 of the display area 101, and the colloid is coated on the upper surface of the support body 20. The upper surface of the support body 20 and the lower surface of the flexible driving substrate 12 are bonded together, wherein the colloid is an optically clear adhesive (OCA).

In step S107, bending a bending area of the display panel and attaching the display panel to the support body.

As shown in FIG. 7, the bending area 102 is bent by a pad bending process, so that the binding area 103 is bent below the support body 20. The bent flexible driving substrate 12 and the support body 20 are adhered and fixed to form a display module. The flip-hip film 15 in the binding area 103 is also connected to a driving circuit board, and a driving chip is disposed on the driving circuit board. The bonding method can be a double-sided tape or glue.

As shown in FIG. 7, the present disclosure further provides a display module, and the display module includes the display panel 10 and the support body 20.

A cross-sectional structure of the display panel 10 includes a bending flexible driving substrate 12 and a display unit 30. The bending flexible driving substrate 12 includes a flexible substrate and a driving layer provided on the flexible substrate.

The bending flexible driving substrate 12 includes a display area 101, a bending area 102, and a binding area 103, wherein the bending flexible driving substrate 12 has a cavity. The binding area 103 is bent from a first side of the support body 20 to a second side of the support body 20 through the bending area 10 to form the cavity. That is, the binding area 103 is bent from the upper surface of the support body 20 to the lower surface of the support body 20 through the bending area 102 to form the cavity.

The display unit is bound to the display area 101. The display unit 30 includes a plurality of miniature light-emitting diodes 131. In one embodiment, the display unit 30 further includes an encapsulating layer 14, and the encapsulating layer 14 covers the miniature light-emitting diodes 131 for protecting the miniature light-emitting diodes 131. The encapsulating layer 14 is an alternating layer with an inorganic layer and an organic layer. The support body 20 is disposed in the cavity, and the shape of a longitudinal section of the support body is a rounded rectangle. In one embodiment, in order to prevent the stitching seam from exceeding the display area, the size of the support body 20 is smaller than the size of the display area 101.

In order to improve the stability of the display module, the support body 20 is attached to the inner wall of the cavity 20. In one embodiment, the display area 101 is attached to a surface of the first side (upper side) of the support body 20, and the bending area 102 is attached to a side wall of the support body 20. The binding area 103 is attached to the surface of the second side (lower side) of the support body 20.

As shown FIG. 8, the support body 20 includes a support plate 21 and a heat dissipation layer 22. In order to facilitate the display module to dissipate heat, the material of the heat dissipation layer 23 is copper. The material of the support plate 21 is one of glass, polyimide, polyethylene terephthalate, and polyaluminum chloride. The thickness of the support plate 21 is smaller than a preset thickness, and the preset thickness is, for example, 500 um, so that the thickness of the support body can be reduced.

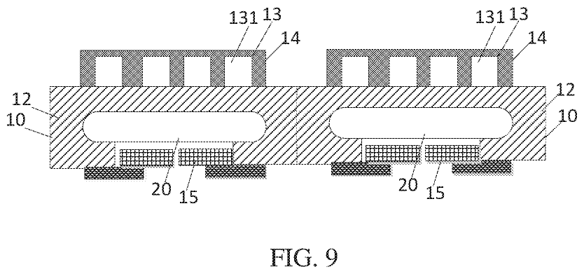

As shown FIG. 9, the present disclosure also provides a display device, which includes two display modules 10 described above, and the two display modules are spliced together to form a display device. It can be understood that the number of the display modules may be two or more.

The display device further includes a back plate (not shown), and the back plate has a receiving cavity, and at least two of the display modules 10 are spliced in the receiving cavity.

The present disclosure adopts the support body in a rounded rectangle, which not only realizes a display module with an extremely narrow frame, but also enables a smooth transition of the bending area, so as to avoid damage to the display area due to the stress on the bending area, and improve the product yields.

The display module, the preparation method thereof, and the electronic device of the present disclosure, the display module includes a support body and a display panel, wherein a cross-sectional structure of the display panel includes: a bending flexible driving substrate including a display area, a bending area, and a binding area, wherein the bending flexible driving substrate has a cavity; and a display unit bound to the display area, wherein the display unit includes a plurality of miniature light-emitting diodes; wherein the support body is provided in the cavity, and a shape of a longitudinal section of the support body is a rounded rectangle. As a result of the shape of the longitudinal section of the support body being a rounded rectangle, the impact of large stress in the bending area is avoided, thereby avoiding damage to the display area and improving product yields.

In summary, although the present disclosure has been disclosed as above with preferred embodiments, however, the foregoing preferred embodiments are not intended to limit the present disclosure. Those of ordinary skill in the art can make various modifications and decorations without departing from the spirit and scope of this present disclosure. Therefore, the protection scope of this present disclosure is subject to the scope defined by the claims.

What is claimed is:

1. A display module, comprising:
a support body; and
a display panel, wherein a cross-sectional structure of the display panel includes:
a bending flexible driving substrate including a display area, a bending area, and a binding area, wherein the bending flexible driving substrate has a cavity; and
a display unit bound to the display area, wherein the display unit includes a plurality of miniature light-emitting diodes;
wherein the support body is provided in the cavity, and a shape of a longitudinal section of the support body is rounded rectangle.

2. The display module according to claim 1, wherein the support body is attached to an inner wall of the cavity.

3. The display module according to claim 2, wherein the display area is attached to a surface of a first side of the support body; the bending area is attached to a side wall of the support body; the binding area is attached to a surface of the second side of the support body.

4. The display module according to claim 1, wherein the support body further includes a support plate and a heat dissipation layer disposed below the support plate.

5. The display module according to claim 4, wherein a material of the support plate includes at least one of glass, polyimide, polyethylene terephthalate, and polyaluminum chloride.

6. The display module according to claim 4, wherein a thickness of the support plate is less than a preset thickness.

7. The display module according to claim 1, wherein a size of the support body is smaller than a size of the display area.

8. The display module according to claim 1, wherein the bending flexible driving substrate includes a flexible substrate and a driving layer provided on the flexible substrate.

9. A preparation method of a display module, comprising steps of:
preparing a flexible driving substrate on a glass substrate;
moving a miniature light-emitting diode chip to the flexible driving substrate and perform an encapsulation to obtain a display panel, wherein the miniature light-emitting diode chip includes a plurality of miniature light-emitting diodes;
bonding a flip-chip film in a binding area of the display panel;
providing a flexible protective film on the display panel;
removing the glass substrate under the flexible driving substrate;
attaching the support body to a side of the display panel located in a display area away from the miniature light-emitting diode chip, wherein a shape of a longitudinal section of the support body is rounded rectangle; and
bending a bending area of the display panel and attaching the display panel to the support body.

10. The preparation method of the display module according to claim 9, wherein the support body is attached to an inner wall of a cavity.

11. The preparation method of the display module according to claim 9, wherein the support body further includes a support plate and a heat dissipation layer disposed below the support plate.

12. The preparation method of the display module according to claim 9, wherein a size of the support body is smaller than a size of the display area.

13. An electronic device, comprising:
at least two display modules, wherein the display module includes:
a support body; and
a display panel, wherein a cross-sectional structure of the display panel includes:
a bending flexible driving substrate including a display area, a bending area, and a binding area, wherein the bending flexible driving substrate has a cavity; and
a display unit bound to the display area, wherein the display unit includes a plurality of miniature light-emitting diodes;
wherein the support body is provided in the cavity, and a shape of a longitudinal section of the support body is rounded rectangle.

14. The electronic device according to claim 13, wherein the support body is attached to an inner wall of the cavity.

15. The electronic device according to claim 14, wherein the display area attached to a surface of a first side of the support body; the bending area is attached to a side wall of the support body; the binding area is attached to a surface of the second side of the support body.

16. The electronic device according to claim 13, wherein the support body further includes a support plate and a heat dissipation layer disposed below the support plate.

17. The electronic device according to claim 16, wherein a material of the support plate includes at least one of glass, polyimide, polyethylene terephthalate, and polyaluminum chloride.

18. The electronic device according to claim 16, wherein a thickness of the support plate is less than a preset thickness.

19. The electronic device according to claim 13, wherein a size of the support body is smaller than a size of the display area.

20. The electronic device according to claim 13, wherein the bending flexible driving substrate includes a flexible substrate and a driving layer provided on the flexible substrate.
